(19) United States
(12) Patent Application Publication
(10) Pub. No.: US 2026/0165149 A1
(43) Pub. Date: Jun. 11, 2026

(54) FAN-OUT WAFER-LEVEL PACKAGING UNIT

(71) Applicant: WALTON ADVANCED ENGINEERING, INC., KAOHSIUNG (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 19/178,889

(22) Filed: Apr. 15, 2025

(30) Foreign Application Priority Data
Apr. 19, 2024 (TW) 113114824

(51) Int. Cl. H10W 70/09; H10W 90/10

(52) U.S. Cl. CPC H10W 70/09; H10W 90/10

(57) ABSTRACT

A fan-out wafer-level packaging (FOWLP) unit which includes a substrate, at least two dies, a first dielectric layer, a second dielectric layer, conductive circuits, and an outer protective layer is provided. The conductive circuits are formed by a metal paste filled in first slots of the first dielectric layer and second slots of the second dielectric layer. One end of the conductive circuit is electrically connected to a die pad of the die while the other end is exposed through an opening of the outer protective layer and formed a bonding pad in the opening. At least one of the bonding pads is located around a chip area on a second surface of the die. The dies are electrically connected to the outside through the die pads, the conductive circuits, and the bonding pads. Thereby problems including higher manufacturing cost and less environmental benefit can be solved.

### CROSS-REFERENCE TO RELATED APPLICATIONS

This non-provisional application claims priority under 35 U.S.C. § 119(a) on Patent Application No(s). 113114824 filed in Taiwan, R.O.C. on Apr. 19, 2024, the entire contents of which are hereby incorporated by reference.

### BACKGROUND OF THE INVENTION

The present invention relates to a chip packaging unit, especially to a fan-out wafer level packaging (FOWLP) unit.

Packaging technology with features of compact design, high efficiency and reliability is a trend in semiconductor industry. In the semiconductor packaging, Fan-Out Wafer Level Packaging (FOWLP) is a packaging technology available now.

In the advanced packaging process such as FOWLP, a redistribution layer (RDL) is the most critical because respective conductive circuits in the RDL make a plurality of die pads on dies have electrical extension in the XY plane and interconnections. Thus a plurality of bonding pads is arranged around the die in a more distributed manner. Thereby design, space, and reliability of the respective conductive circuits are effectively improved. Yet how to keep balance between the electrical extension in the XY plane and interconnections of the conductive circuits and the compact design to a certain degree. The most critical point is the manufacturing of the respective conductive circuits in the RDL. However, the formation of the respective conductive circuits in the RDL of the FOWLP technology available now is by chemical plating or electroplating. Thus not only cost for material and manufacturing is high, the manufacturing process is also not environmental friendly.

Moreover, in order to provide products with higher performance or more functions, at least two dies are disposed in FOWLP unit and the multi-chip type FOWLP unit is integrated by RDL. At the moment, space requirement for designing respective conductive circuits in the RDL of the FOWLP unit is increased and manufacturing of the conductive circuits in the RDL becomes more crucial.

### SUMMARY OF THE INVENTION

Therefore, it is a primary object of the present invention to provide a fan-out wafer-level packaging (FOWLP) unit which includes a substrate, at least two dies, a first dielectric layer, a second dielectric layer, a plurality of conductive circuits, and an outer protective layer. The respective conductive circuits are formed by a metal paste filled in a plurality of first slots located at the first dielectric layer and a plurality of second slots located at the second dielectric layer. One end of the respective conductive circuits is electrically connected to a correspondingly die pad of the die while the other end is exposed through an opening of the outer protective layer and forming a bonding pad in the opening correspondingly. At least one of the bonding pads is located around a chip area on a second surface of the die to form the FOWLP unit. The respective dies are electrically connected to the outside through the die pads, the conductive circuits, and the bonding pads. Thereby the problems of the FOWLP technology available now generated during manufacturing of the conductive circuits including higher manufacturing cost and less environmental benefit can be solved effectively.

In order to achieve the above object, a fan-out wafer-level packaging (FOWLP) unit according to the present invention is provided. The FOWLP unit includes a substrate, at least two dies, a first dielectric layer, a second dielectric layer, a plurality of conductive circuits, and an outer protective layer. The dies are cut from the same wafer or different wafers and provided with a first surface and a second surface opposite to each other. The dies are arranged at the substrate in parallel and spaced apart from each other. The first surface of the die is fixed on the substrate while the second surface of the die is provided with a plurality of die pads. An area just above the second surface is defined as a chip area. The first dielectric layer is mounted to the substrate and the second surface of the dies and provided with a plurality of first slots extending in a horizontal direction. The respective die pads of the dies are exposed through the respective first slots. The second dielectric layer is disposed over the first dielectric layer and provided with a plurality of second slots extending in a horizontal direction. The respective second slots are communicating with the respective first slots. The respective conductive circuits are formed by a metal paste filled in the respective first slots and the respective second slots. The respective conductive circuits are electrically connected with the respective die pads of the dies. The outer protective layer is arranged over the second dielectric layer and provided with a plurality of openings. At least two of the openings is located around the chip area on the second surface of the dies. Each of the conductive circuits is exposed through the corresponding opening and forming a bonding pad in the corresponding opening. The dies are electrically connected to the outside through the die pads, the conductive circuits, and the bonding pads around the chip area on the second surface of the dies corresponding. Thereby the FOWLP unit is formed.

A method of manufacturing the fan-out wafer-level packaging (FOWLP) unit according to the present invention includes the following steps. Step S1: providing a substrate. Step S2: disposing a plurality of dies cut from the same wafer or different wafers on the substrate and arranging the dies in parallel and spaced apart from one another. Each of the dies includes a first surface and a second surface opposite to the first surface. The first surface of the die is arranged at the substrate while the second surface of the die is provided with a plurality of die pads. An area just above the second surface is defined as a chip area. Step S3: paving a first dielectric layer over the substrate and the second surface of the respective dies. Step S4: forming a plurality of first slots extending horizontally on the first dielectric layer and exposing the respective die pads of the respective dies through the respective first slots. Step S5: arranging a second dielectric layer over the first dielectric layer. Step S6: forming a plurality of second slots extending horizontally on the second dielectric layer and the respective second slots communicating with the respective first slots. Step S7: filling a metal paste into the respective first slots and the respective second slots and a level of the metal paste is higher than a surface of the second dielectric layer. Step S8: grinding the metal paste with the level higher than the surface of the second dielectric layer to make a surface of the metal paste flush with the surface of the second dielectric layer and forming a plurality of conductive circuits. Step S9: covering the second dielectric layer with an outer protective layer. Step S10: forming a plurality of openings on the outer protective layer and at least one of the openings is formed around the chip area on the second surface of the die so that the respective conductive circuits are exposed through the respective openings to form a bonding pad in each of the openings. Step S11: performing cutting to form a plurality of fan-out wafer-level packaging (FOWLP) units 1 each of which includes at least the two dies packaged therein.

Preferably, the dies are cut from the same wafer.

Preferably, the dies are cut from different wafers.

Preferably, the second surfaces of the respective dies on the substrate are at the same level.

Preferably, the substrate includes a silicon (Si) substrate, a glass substrate, and a ceramic substrate.

Preferably, the metal paste includes silver paste, nano-scale silver paste, copper paste, and nano-scale copper paste.

Preferably, the first surface of the die is disposed on the substrate by a die attach film (DAF).

Preferably, each of the openings is provided with a solder ball which is electrically connected with the bonding pad in the opening.

Preferably, the FOWLP unit can be electrically connected to and disposed on a printed circuit board (PCB) by the respective solder balls.

### BRIEF DESCRIPTION OF THE DRAWINGS

FIG. 1 is a side sectional view showing a fan-out wafer level packaging unit disposed on a printed circuit board of an embodiment according to the present invention;

FIG. 2 is a side sectional view showing a die arranged at a substrate of an embodiment according to the present invention;

FIG. 3 is a side sectional view showing a first dielectric layer disposed on a substrate and a second surface of a die of an embodiment according to the present invention;

FIG. 4 is a side sectional view showing a second dielectric layer disposed on a first dielectric layer of an embodiment according to the present invention;

FIG. 5 is a side sectional view showing a first slot and a second slot both filled with metal paste of an embodiment according to the present invention;

FIG. 6 is a side sectional view showing grinding of the metal paste on a surface of a second dielectric layer in the embodiment in FIG. 5 according to the present invention;

FIG. 7 is a side sectional view showing formation of a plurality of openings on an outer protective layer of an embodiment according to the present invention;

FIG. 8 is a side sectional view of a fan-out wafer-level packaging (FOWLP) unit of an embodiment according to the present invention.

### DETAILED DESCRIPTION OF THE PREFFERED EMBODIMENT

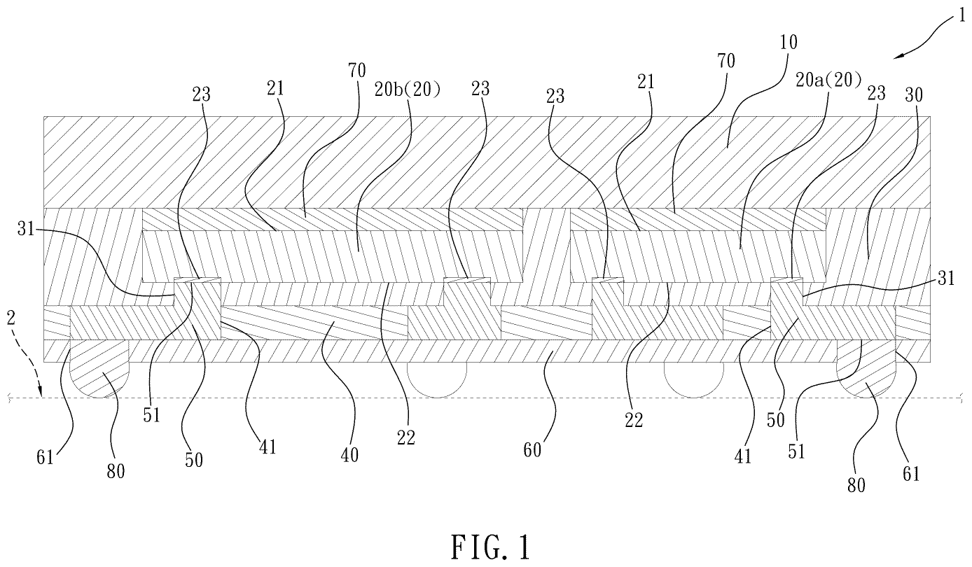

Refer to FIG. 1, a fan-out wafer-level packaging (FOWLP) unit 1 according to the present invention includes a substrate 10, at least two dies 20, a first dielectric layer 30, a second dielectric layer 40, a plurality of conductive circuits 50, and an outer protective layer 60.

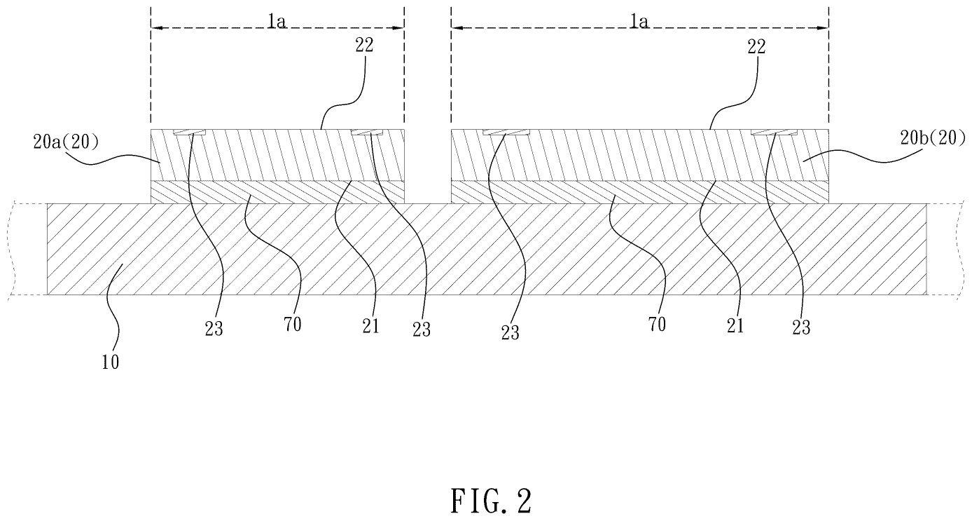

The substrate 10 includes silicon (Si) substrate, glass substrate, and ceramic substrate, but not limited, as shown in FIG. 2. This is beneficial to diversified product development and applications.

The dies 20 are cut from the same wafer or different wafers and each of the dies 20 is provided with a first surface 21 and a second surface 22 opposite to the first surface 21. The dies 20 are arranged at the substrate 10 in parallel and spaced apart from each other. The first surface 21 of the die 20 is fixed on the substrate 10 while the second surface 22 of the die 20 is provided with a plurality of die pads 23. As shown in FIG. 2, an area just above the second surface 22 is defined as a chip area 1a. In the embodiment shown in FIG. 2, the number of the die pads 23 on the respective dies 20 is two and this is only an example, not intended to limit the present invention.

In the embodiment shown in FIG. 1-8, the dies 20 on the substrate 10 further includes a first die 20a and a second die 20b, but not limited. The two dies 20 are taken as an example in this embodiment, not intend to limit the present invention.

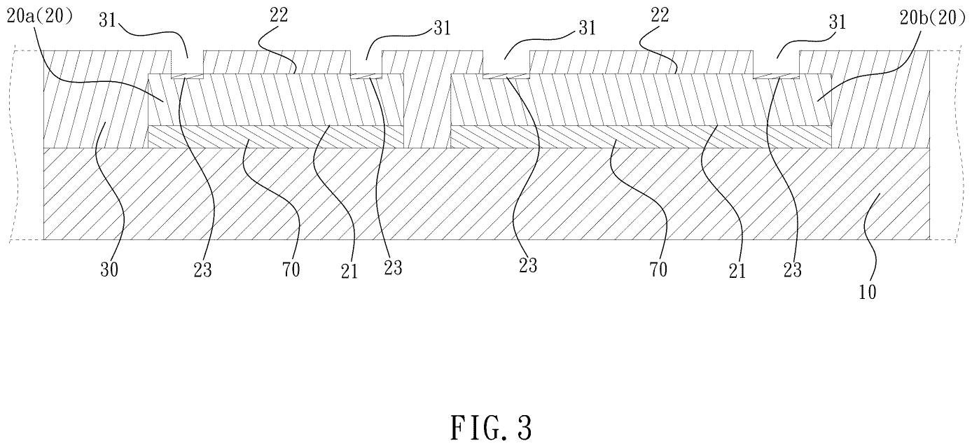

Refer to FIG. 3, the first dielectric layer 30 is mounted to both the substrate 10 and the second surface 22 of the respective dies 20 (20a, 20b) and provided with a plurality of first slots 31 extending in a horizontal direction. The respective die pads 23 of the respective dies 20 (20a, 20b) are exposed through the respective first slots 31.

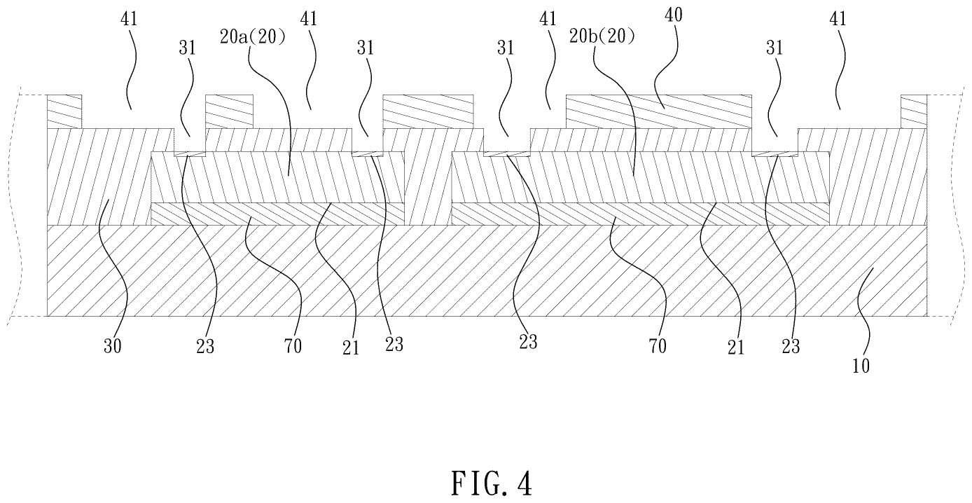

The second dielectric layer 40 is disposed over the first dielectric layer 30 and provided with a plurality of second slots 41 extending in a horizontal direction. The respective second slots 41 are communicating with the respective first slots 31, as shown in FIG. 4.

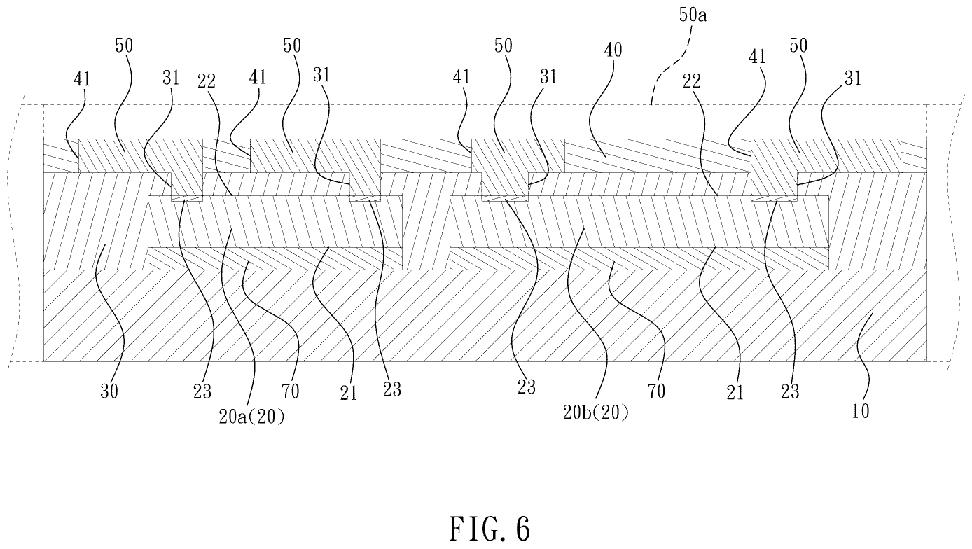

The respective conductive circuits 50 are formed by a metal paste 50a filled in the respective first slots 31 and the respective second slots 41. As shown in FIG. 6, the respective conductive circuits 50 are electrically connected with the respective die pads 23 of the respective dies 20 (20a, 20b). The metal paste 50a includes, but not limited to silver paste, nano-scale silver paste, copper paste, and nano-scale copper paste. The nano-scale silver paste has features of low cost, high conductivity, and ability to be sintered at low temperature. The nano-scale silver paste is a common material available now and no more detailed description is given.

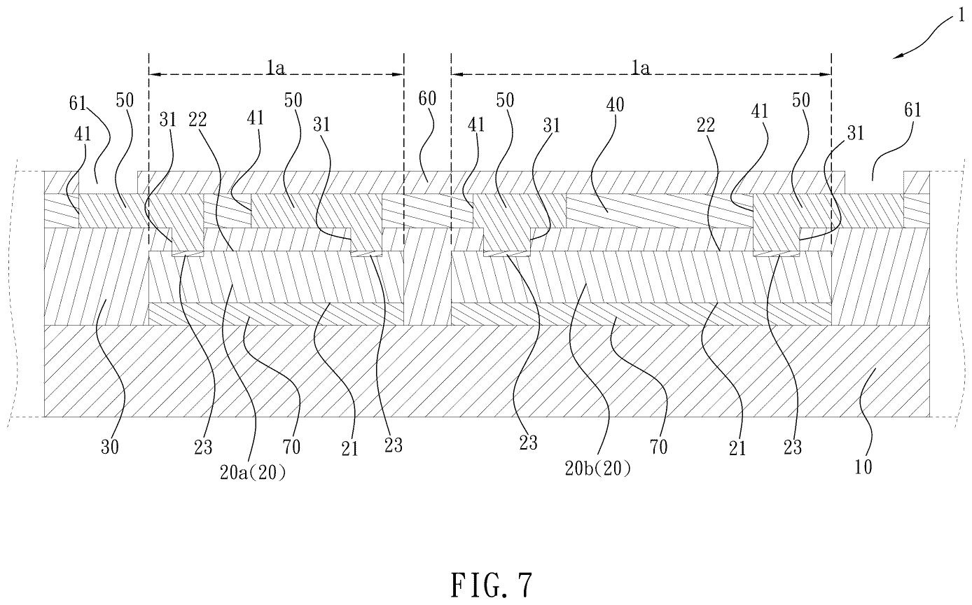

The outer protective layer 60 is arranged over the second dielectric layer 40 and provided with a plurality of openings 61. At least two of the openings 61 are located around the chip area 1a on the second surface 22 of the respective dies 20 (20a, 20b), as shown in FIG. 7. The respective conductive circuits 50 are exposed through the respective openings 61 and forming a bonding pad 51 in each of the openings 61. In FIG. 7, there are two openings 61 in the outer protective layer 60 in this embodiment. This is only an example, not intended to limit the present invention.

The respective dies 20 (20a, 20b) are electrically connected to the outside through the respective die pads 23, the respective conductive circuits 50, and the respective bonding pads 51 around the chip area 1a on the second surface 22 of the respective dies 20 (20a, 20b) in turn. Thereby the fan-out wafer-level packaging (FOWLP) unit 1 is formed, as shown in FIG. 7.

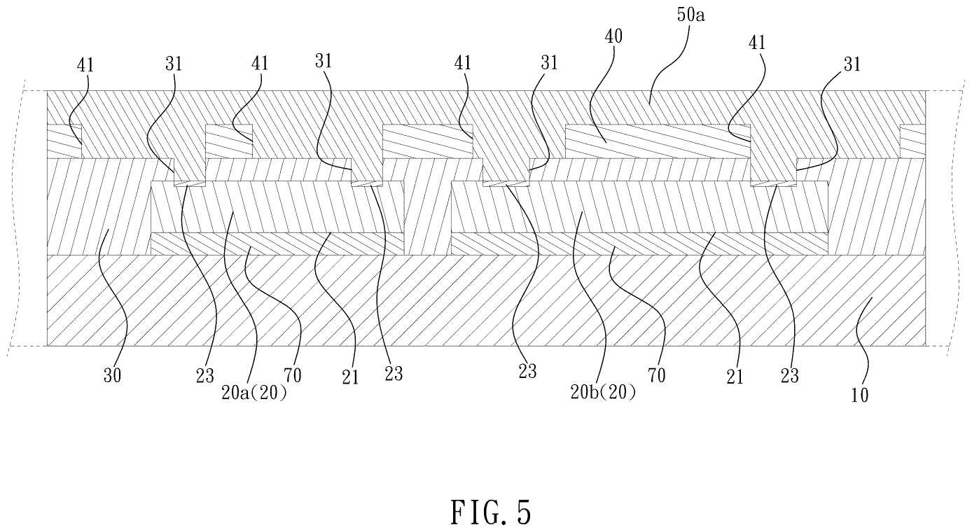

A method of manufacturing the fan-out wafer-level packaging (FOWLP) unit 1 according to the present invention includes the following steps.
Step S1: providing a substrate 10, as shown in FIG. 2.
Step S2: arranging a plurality of dies 20 cut from at the same wafer or different wafers on the substrate 10 in parallel and spaced from each other, as shown in FIG. 2. Each of the dies 20 includes a first surface 21 and a second surface 22 opposite to the first surface 21. The first surface 21 of the die 20 is arranged at the substrate 10 while the second surface 22 of the die 20 is provided with a plurality of die pads 23. An area just above the second surface 22 of the die 20 is defined as a chip area 1a.
Step S3: paving a first dielectric layer 30 over both the substrate 10 and the second surface 22 of the die 20, as shown in FIG. 3.
Step S4: forming a plurality of first slots 31 extending horizontally on the first dielectric layer 30 and exposing the respective die pads 23 of the respective dies 20 through the respective first slots 31, as shown in FIG. 3.
Step S5: paving a second dielectric layer 40 over the first dielectric layer 30, as shown in FIG. 4.
Step S6: forming a plurality of second slots 41 extending horizontally on the second dielectric layer 40 and the respective second slots 41 communicating with the respective first slots 31, as shown in FIG. 4.
Step S7: filling a metal paste 50a into the respective first slots 31 and the respective second slots 41 and a level of the metal paste 50a is higher than a surface of the second dielectric layer 40, as shown in FIG. 5.
S8: grinding the metal paste 50a with the level higher than the surface of the second dielectric layer 40 to make a surface of the metal paste 50a flush with the surface of the second dielectric layer 40 and form a plurality of conductive circuits 50, as shown in FIG. 6.
Step S9: covering the second dielectric layer 40 with an outer protective layer 60, as shown in FIG. 7.
Step S10: forming a plurality of openings 61 on the outer protective layer 60 and at least one of the openings 61 is formed around the chip area 1a on the second surface 22 of the die 20 so that the respective conductive circuits 50 are exposed through the respective openings 61 to form a bonding pad 51 in each of the openings 61, as shown in FIG. 7.
Step S11: performing cutting to form a plurality of fan-out wafer-level packaging (FOWLP) units 1 each of which is packaged with at least two dies 20 (the first die 20a and the second die 20b) therein, as shown in FIG. 7. In the embodiment shown in FIG. 7, one fan-out wafer-level packaging (FOWLP) unit 1 is taken as an example, but not intended to limit the present invention.

The steps S3-S10 during a process of the method of manufacturing the FOWLP unit 1 are considered as key steps of manufacturing the redistribution layer (RDL) of the FOWLP unit 1. The steps S4-S8 are easy to be implemented precisely so that the manufacturing process is simplified and the respective conductive circuits 50 in the RDL have electrical extension in the XY plane and interconnections. At the same time, the FOWLP unit 1 manufactured still has compact size and light weight to some degree, even under the condition that the FOWLP unit 1 contains at least two of the dies 20.

Refer to FIG. 2, when the dies 20 are cut from the same wafer, the respective dies 20 have the same specifications, effectiveness, or functions.

Refer to FIG. 2, when the dies 20 are cut from different wafers, this helps diversified applications of the product. The respective dies 20 have different specifications, effectiveness, or functions. As shown in FIG. 2, the size of the first die 20a is smaller than the size of the second die 20b.

Refer to FIG. 2, the second surfaces 22 of the respective dies 20 on the substrate 10 are at the same level. Thereby the first slots 31 of the first dielectric layer 30 and the second slots 41 of the second dielectric layer 40 can be extended and formed smoothly and flatly. This helps the following structures stocked over the dies 20 keep flatness and evenness in order to increase reliability of the product.

Refer to FIG. 2, the first surface 21 of the die 20 is arranged at the substrate 10 by a die attach film (DAF) 70, but not limited.

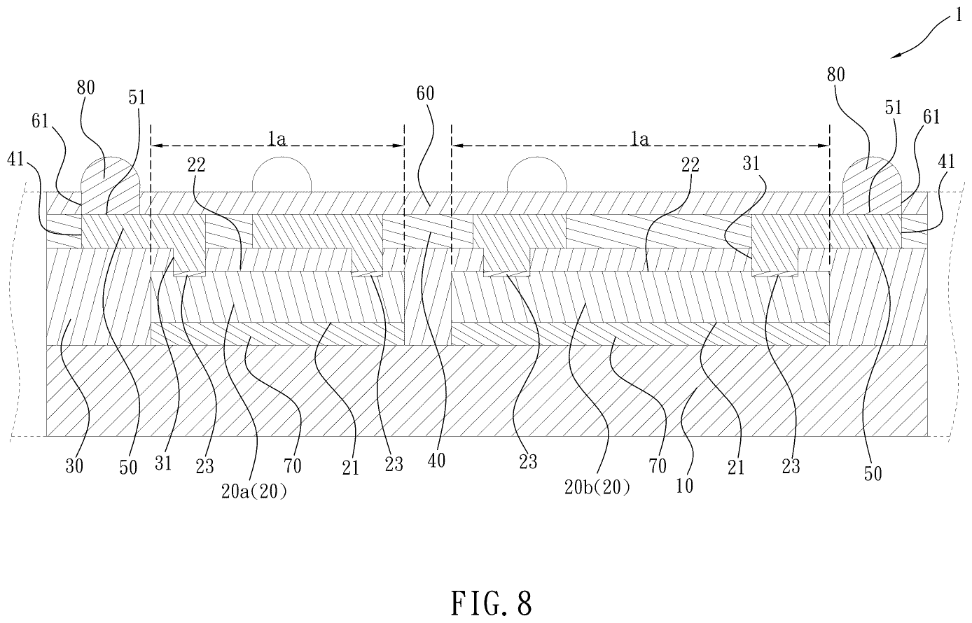

Refer to FIG. 8, each of the openings 61 is provided with a solder ball 80 which is electrically connected with the bonding pad 51 in the opening 61.

Refer to FIG. 1, the FOWLP unit 1 can be electrically connected and disposed on a printed circuit board (PCB) 2 by the respective solder balls 80.

Compared with the FOWLP unit available now, the FOWLP unit 1 of the present invention has the following advantages.
(1) The steps S3-S10 of the present method of manufacturing the FOWLP unit 1 are simplified and easily-implemented steps and this is especially helpful in reduction of a thickness of the packaging unit. Thus the manufacturing process of the present invention is not only more simplified and with reduced cost, but also improving use efficiency and reliability of the FOWLP unit 1.
(2) The steps S3-S8 of the method of manufacturing the respective conductive circuits 50 of the present invention can effectively solve the problems of the FOWLP technology available now generated during manufacturing of the respective conductive circuits 50 including higher manufacturing cost and less environmental benefit.
(3) The present invention makes the multi-chip type FOWLP unit keep compact design to a certain degree for providing products with higher performance (such as the dies 20 with the same specifications, effectiveness, or functions) or more functions (such as the dies 20 with different specifications, effectiveness, or functions). Thereby market competitiveness of the product is improved.

1. A fan-out wafer-level packaging (FOWLP) unit comprising:
a substrate;
at least two dies cut from the same wafer or different wafers and provided with a first surface and a second surface opposite to each other; the dies arranged at the substrate in parallel and spaced apart from each other; the first surface of the die fixed on the substrate and the second surface of the die provided with a plurality of die pads; an area just above the second surface being defined as a chip area;
a first dielectric layer mounted to the substrate and the second surface of the die and provided with a plurality of first slots extending in a horizontal direction; wherein each of the die pads of the die is exposed through the corresponding first slot;
a second dielectric layer disposed over the first dielectric layer and provided with a plurality of second slots extending in a horizontal direction; the second slots communicating with the first slots correspondingly;
a plurality of conductive circuits formed by a metal paste filled in the respective first slots and the respective second slots; the respective conductive circuits electrically connected with the respective die pads of the die; and
an outer protective layer arranged over the second dielectric layer and provided with a plurality of openings; at least two of the openings located around the chip area on the second surface of the die; wherein each of the conductive circuits is exposed through the corresponding opening and forming a bonding pad in the opening;
wherein the dies are electrically connected to the outside through the respective die pads, the respective conductive circuits, and the respective bonding pads around the chip area on the second surface of the dies to form the FOWLP unit;
wherein a method of manufacturing the fan-out wafer-level packaging (FOWLP) unit comprising the steps of:
Step S1: providing a substrate;
Step S2: arranging a plurality of dies cut from the same wafer or different wafers on the substrate and the dies are spaced apart from one another;
wherein each of the dies includes a first surface and a second surface opposite to the first surface; the first surface of the die is arranged at the substrate while the second surface of the die is provided with a plurality of die pads and an area above the second surface of the die is defined as a chip area;
Step S3: paving a first dielectric layer over the substrate and the second surface of the respective dies;
Step S4: forming a plurality of first slots extending horizontally on the first dielectric layer and exposing the respective die pads of the respective dies through the respective first slots;
Step S5: covering the first dielectric layer with a second dielectric layer;
Step S6: forming a plurality of second slots extending horizontally on the second dielectric layer and the respective second slots communicating with the respective first slots;
Step S7: filling a metal paste into the respective first slots and the respective second slots and a level of the metal paste is higher than a surface of the second dielectric layer;
Step S8: grinding the metal paste with the level higher than the surface of the second dielectric layer to make a surface of the metal paste flush with the surface of the second dielectric layer and form a plurality of conductive circuits;
Step S9: covering the second dielectric layer with an outer protective layer;
Step S10: forming a plurality of openings on the outer protective layer and at least one of the openings is formed around the chip area on the second surface of the die so that each of the conductive circuits is exposed through the corresponding opening and forming a bonding pad in the corresponding opening; and
Step S11: performing cutting to form a plurality of fan-out wafer-level packaging (FOWLP) units each of which includes at least the two dies packaged therein.

2. The fan-out wafer-level packaging (FOWLP) unit as claimed in claim 1, wherein the dies are cut from the same wafer.

3. The fan-out wafer-level packaging (FOWLP) unit as claimed in claim 1, wherein the dies are cut from different wafers.

4. The fan-out wafer-level packaging (FOWLP) unit as claimed in claim 1, wherein the second surfaces of the dies are at the same level.

5. The fan-out wafer-level packaging (FOWLP) unit as claimed in claim 1, wherein the substrate is selected from the group consisting of silicon (Si) substrate, glass substrate, and ceramic substrate.

6. The fan-out wafer-level packaging (FOWLP) unit as claimed in claim 1, wherein the metal paste is selected from the group consisting of silver paste, nano-scale silver paste, copper paste, and nano-scale copper paste.

7. The fan-out wafer-level packaging (FOWLP) unit as claimed in claim 1, wherein the first surface of each of the dies is arranged at the substrate by a die attach film (DAF).

8. The fan-out wafer-level packaging (FOWLP) unit as claimed in claim 1, wherein each of the openings is provided with a solder ball which is electrically connected with the bonding pad in the opening.

9. The fan-out wafer-level packaging (FOWLP) unit as claimed in claim 8, wherein the fan-out wafer-level packaging (FOWLP) unit is electrically connected to and disposed on a printed circuit board (PCB) by the solder balls.
